(19) United States
(12) Patent Application Publication
(10) Pub. No.: US 2025/0063754 A1
(43) Pub. Date: Feb. 20, 2025

(54) SEMICONDUCTOR DEVICE, METHOD FOR MANUFACTURING SEMICONDUCTOR DEVICE, AND ELECTRONIC DEVICE

(71) Applicant: Fujitsu Limited, Kawasaki-shi (JP)

(72) Inventors: Kenji HOMMA, Atsugi (JP); Atsushi YAMADA, Hiratsuka (JP)

(73) Assignee: Fujitsu Limited, Kawasaki-shi (JP)

(21) Appl. No.: 18/803,043

(22) Filed: Aug. 13, 2024

(30) Foreign Application Priority Data
Aug. 16, 2023 (JP) 2023-132475

(51) Int. Cl. H01L 29/778; H01L 29/20; H01L 29/66

(52) U.S. Cl. CPC H01L 29/7786; H01L 29/2003; H01L 29/66462

(57) ABSTRACT

a semiconductor device includes: a channel layer that includes a first nitride semiconductor; a barrier layer provided on a first surface side of the channel layer and includes a second nitride semiconductor; a source electrode and a drain electrode provided on a second surface side opposite to the channel layer side, of the barrier layer; a gate electrode provided between the source electrode and the drain electrode, on the second surface side of the barrier layer; and a polarization layer that is provided between the gate electrode and the drain electrode, from among between the gate electrode and the source electrode and between the gate electrode and the drain electrode on the second surface side of the barrier layer, includes a third nitride semiconductor that contains Al, and has an Al composition that decreases from the barrier layer side toward a third surface side opposite to the barrier layer side.

### CROSS-REFERENCE TO RELATED APPLICATION

This application is based upon and claims the benefit of priority of the prior Japanese Patent Application No. 2023-132475, filed on Aug. 16, 2023, the entire contents of which are incorporated herein by reference.

### FIELD

The embodiments discussed herein are related to a semiconductor device, a method for manufacturing the semiconductor device, and an electronic device.

### BACKGROUND

As one semiconductor device, a high electron mobility transistor (HEMT) including a barrier layer and a channel layer using a nitride semiconductor has been known. The channel layer is also referred to as an electron transit layer or the like, and the barrier layer is also referred to as an electron supply layer or the like.

For example, a technique has been known that a source, drain, and gate contacts are provided on the barrier layer on the channel layer and a regrowth material, for example, a regrowth material of which an Al composition decreases from one or a value close to one upward is provided between the gate and the source, and the drain.

Furthermore, a technique has been known that a cap layer including a gallium nitride (GaN) layer, an aluminum nitride (AlN) layer, and an aluminum gallium nitride (AlGaN) layer provided between the GaN layer and the AlN layer and having an Al composition increasing toward the AlN layer is provided on an electron supply layer on an electron transit layer.

U.S. Pat. No. 10,553,697 and Japanese Laid-open Patent Publication No. 2012-119582 are disclosed as related art.

### SUMMARY

According to an aspect of the embodiments, a semiconductor device includes: a channel layer that includes a first nitride semiconductor; a barrier layer that is provided on a first surface side of the channel layer and includes a second nitride semiconductor; a source electrode and a drain electrode provided on a second surface side opposite to the channel layer side, of the barrier layer; a gate electrode provided between the source electrode and the drain electrode, on the second surface side of the barrier layer; and a polarization layer that is provided between the gate electrode and the drain electrode, from among between the gate electrode and the source electrode and between the gate electrode and the drain electrode on the second surface side of the barrier layer, includes a third nitride semiconductor that contains Al, and has an Al composition that decreases from the barrier layer side toward a third surface side opposite to the barrier layer side.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram for explaining an example of a semiconductor device according to a first embodiment;

FIGS. 2A and 2B are diagrams for explaining a configuration example of a polarization layer of the semiconductor device according to the first embodiment;

FIGS. 3A to 3C are diagrams for explaining a relationship between an Al composition of a nitride semiconductor and spontaneous polarization;

FIGS. 4A and 4B are diagrams for explaining an example of a simulation result of electron concentration in the semiconductor device;

FIGS. 5A to 5E are diagrams for explaining an energy band of an example of the semiconductor device;

FIGS. 6A and 6B are diagrams for explaining an example of a simulation result of an electric field intensity of the semiconductor device;

FIGS. 7A to 7C are diagrams (part 1) for explaining an example of a method for manufacturing the semiconductor device according to the first embodiment;

FIGS. 8A to 8C are diagrams (part 2) for explaining an example of the method for manufacturing the semiconductor device according to the first embodiment;

FIGS. 9A to 9C are diagrams (part 3) for explaining an example of the method for manufacturing the semiconductor device according to the first embodiment;

FIG. 10 is a diagram for explaining an example of a semiconductor device according to a second embodiment;

FIG. 11 is a diagram for explaining an example of a semiconductor package according to a third embodiment;

FIG. 12 is a diagram for explaining an example of a power factor correction circuit according to a fourth embodiment;

FIG. 13 is a diagram for explaining an example of a power supply device according to a fifth embodiment; and

FIG. 14 is a diagram for explaining an example of an amplifier according to a sixth embodiment.

### DESCRIPTION OF EMBODIMENTS

In a semiconductor device such as a HEMT in which a source electrode, a drain electrode, and a gate electrode are provided on a barrier layer on a channel layer, at the time of operation, a relatively high voltage may be applied to a side of the drain electrode. In that case, a relatively high intensity electric field may be applied to an end portion of the gate electrode on the side of the drain electrode. If the electric field intensity at the end portion of the gate electrode on the side of the drain electrode exceeds a limit of a material in the vicinity thereof, there is a possibility that the semiconductor device is broken.

In one aspect, an object of the embodiments is to realize a high-withstand-voltage semiconductor device.

### First Embodiment

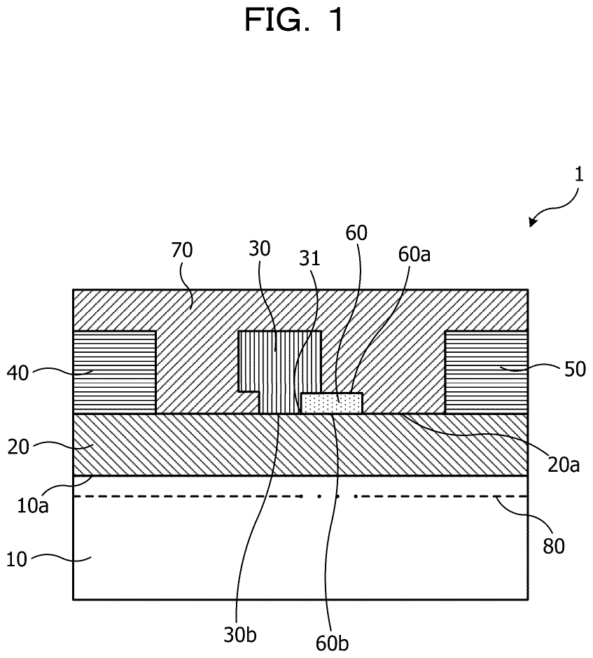

FIG. 1 is a diagram for explaining an example of a semiconductor device according to a first embodiment. In FIG. 1, a main part cross-sectional diagram of an example of the semiconductor device is schematically illustrated.

A semiconductor device 1 illustrated in FIG. 1 is an example of a HEMT. The semiconductor device 1 includes a channel layer 10, a barrier layer 20, a gate electrode 30, a source electrode 40, a drain electrode 50, a polarization layer 60, and an insulation film 70.

A nitride semiconductor, for example, GaN is used for the channel layer 10. In addition to GaN, a nitride semiconductor such as AlGaN or indium gallium nitride (InGaN) may be used for the channel layer 10. The channel layer 10 is formed on a predetermined base substrate (not illustrated) by using, for example, metal organic chemical vapor deposition (MOCVD), a metal organic vapor phase epitaxy (MOVPE) method, a molecular beam epitaxy (MBE) method, or the like. For the base substrate where the channel layer 10 is formed, various substrates of silicon carbide (SiC), GaN, silicon (Si), sapphire, diamond, or the like or various substrates on which a nucleating layer of AlN or the like or a buffer layer is formed or the like is used. The channel layer 10 is formed on the predetermined base substrate so that one surface 10a thereof serves as a (0001) surface, for example, a group III polar surface, for example. The channel layer 10 is also referred to as an electron transit layer or the like.

A nitride semiconductor, for example, AlGaN is used for the barrier layer 20. In addition to AlGaN, a nitride semiconductor such as indium aluminum gallium nitride (InAlGaN) or indium aluminum nitride (InAlN) may be used for the barrier layer 20. The barrier layer 20 is provided on a side of the surface 10a of the channel layer 10. The barrier layer 20 is formed on the surface 10a that is the group III polar surface of the channel layer 10, using the MOVPE method or the like. A surface 20a of the barrier layer 20 on an opposite side to the channel layer 10 side is a (0001) surface, for example, the group III polar surface. The barrier layer 20 is also referred to as an electron supply layer or the like.

Here, for the channel layer 10 and the barrier layer 20, nitride semiconductors having bandgaps different from each other are used. The nitride semiconductor having a larger bandgap than the channel layer 10 is used for the barrier layer 20. Piezoelectric polarization generated in the barrier layer 20 due to spontaneous polarization of the nitride semiconductor of the barrier layer 20 and a distortion caused by a lattice constant difference from the nitride semiconductor of the channel layer 10 generates a two dimensional electron gas (2DEG) region 80 in the channel layer 10. For the channel layer 10 and the barrier layer 20, a nitride semiconductor having a combination such that the 2DEG region 80 is generated in the channel layer 10 is used.

The gate electrode 30 is provided on a side of the surface 20a of the barrier layer 20. A metal material is used for the gate electrode 30. For example, a laminated body having nickel (Ni) and gold (Au) provided thereon is provided as the gate electrode 30. The gate electrode 30 is formed using a vapor deposition method or the like. The gate electrode 30 is provided so as to function as a Schottky electrode, for example. Alternatively, the gate electrode 30 is provided on the side of the surface 20a of the barrier layer 20 via a gate insulation film (not illustrated) and may have a metal insulator semiconductor (MIS) type gate structure.

The source electrode 40 and the drain electrode 50 are provided on the side of the surface 20a of the barrier layer 20. The source electrode 40 and the drain electrode 50 are provided on both sides of the gate electrode 30, to be separated from the gate electrode 30. For example, in order to increase a withstand voltage, so-called asymmetric arrangement may be made in which the gate electrode 30 is closer to the source electrode 40 than the drain electrode 50. A metal material is used for the source electrode 40 and the drain electrode 50. For example, as the source electrode 40 and the drain electrode 50, a laminated body including tantalum (Ta) or titanium (Ti) and aluminum (Al) provided thereon is provided. The source electrode 40 and the drain electrode 50 are formed using the vapor deposition method or the like. The source electrode 40 and the drain electrode 50 are provided so as to function as ohmic electrodes. As long as the source electrode 40 and the drain electrode 50 function as the ohmic electrodes, the source electrode 40 and the drain electrode 50 may be coupled to the barrier layer 20 or may be coupled to the channel layer 10 via the barrier layer 20. In a portion of the barrier layer 20 or the channel layer 10 coupled to the source electrode 40 and the drain electrode 50, a contact layer (regrowth layer) using a nitride semiconductor such as n-type GaN or n-type AlGaN may be provided.

The polarization layer 60 is provided between the gate electrode 30 and the drain electrode 50, on the side of the surface 20a of the barrier layer 20. The polarization layer 60 is provided so as to extend from an end portion of the gate electrode 30 on the side of the drain electrode 50 toward the side of the drain electrode 50. The polarization layer 60 extends from an end 31 of the gate electrode 30 on the side of the drain electrode 50 on a bottom surface 30b facing the barrier layer 20, toward the side of the drain electrode 50. For example, the polarization layer 60 is provided to be separated from the drain electrode 50.

A nitride semiconductor containing Al is used for the polarization layer 60. For example, for the polarization layer 60, a nitride semiconductor represented by a general formula InₓAl_{y}Ga_{1-(x+y)}N(0)≤x≤1, 0≤y≤1, 0≤x+y≤1) is used. Here, the polarization layer 60 has a structure having an inclined Al composition in which an Al composition decreases from a surface 60b on the side of the barrier layer 20 toward a surface 60a on an opposite side to the side of the barrier layer 20.

In the polarization layer 60, a predetermined polarization occurs due to its inclined Al composition. Due to the polarization that occurs in the polarization layer 60, the 2DEG region 80 immediately below the polarization layer 60 is modulated, and electron concentration in the 2DEG region 80 immediately below the polarization layer 60 is reduced. Note that details of the configuration of the polarization layer 60, the polarization that occurs therein, and the modulation of the 2DEG region 80 caused by the polarization will be described layer.

The insulation film 70 is provided to cover the gate electrode 30, the source electrode 40, the drain electrode 50, and the polarization layer 60, on the side of the surface 20a of the barrier layer 20. For the insulation film 70, an insulating material such as silicon nitride (SiN) is used.

Note that, although not illustrated here, between the channel layer 10 and the base substrate where the channel layer 10 is formed, a layer of AlN or the like may be provided as an initial layer, a layer of AlGaN or the like may be provided as a buffer layer, and a layer of GaN or the like doped with iron (Fe) may be provided. In addition, between the channel layer 10 and the base substrate, a layer of AlN, AlGaN, or the like may be provided as a barrier layer (back barrier layer) for realizing a quantum well (quantum confinement) structure. Between the channel layer 10 and the barrier layer 20, a layer of AlGaN, InGaN, or the like may be provided as a spacer layer. On the side of the surface 20a of the barrier layer 20, a layer of GaN or the like may be provided as a cap layer. In the semiconductor device 1, in addition to the channel layer 10 and the barrier layer 20, one or two or more of such an initial layer, buffer layer, spacer layer, back barrier layer, cap layer, or the like may be included.

Note that the surface 10a of the channel layer 10 is also referred to as a “first surface”. The surface 20a of the barrier layer 20 is also referred to as a “second surface”. The surface 60a of the polarization layer 60 is also referred to as a “third surface”, and the surface 60b is also referred to as a “fourth surface”. The nitride semiconductor included in the channel layer 10 is also referred to as a “first nitride semiconductor”. The nitride semiconductor included in the barrier layer 20 is also referred to as a “second nitride semiconductor”. The nitride semiconductor included in the polarization layer 60 is also referred to as a “third nitride semiconductor”.

At the time of an operation of the semiconductor device 1 having the above configuration, a predetermined voltage is applied between the source electrode 40 and the drain electrode 50, and a predetermined voltage is applied to the gate electrode 30. An electric field effect caused by the voltage applied to the gate electrode 30 controls an amount of charges passing through the 2DEG region 80 immediately below the gate electrode 30 between the source electrode 40 and the drain electrode 50, and an output current is controlled. In this way, a transistor function of the semiconductor device 1 is realized.

Typically, at the time of the operation of the semiconductor device, a relatively high voltage may be applied to a side of the drain electrode. In that case, a relatively high intensity electric field may be applied to an end portion of the gate electrode on the side of the drain electrode. If an electric field intensity at the end portion of the gate electrode on the side of the drain electrode exceeds a limit of a material in the vicinity thereof, there is a possibility that the semiconductor device is broken.

On the other hand, in the semiconductor device 1 having the above configuration, in the end portion of the gate electrode 30 on the side of the drain electrode 50, the polarization layer 60 having the inclined Al composition is provided so as to extend from the end portion toward the side of the drain electrode 50. Due to the polarization that occurs in the polarization layer 60, the 2DEG region 80 immediately below the polarization layer 60 is modulated, and the electron concentration is reduced. As a result, electric field concentration near the end portion of the gate electrode 30 on the side of the drain electrode 50 is alleviated. As a result, the material near the end portion is prevented from reaching a breakdown field, and the semiconductor device 1 is prevented from being broken. By providing the polarization layer 60, the high-withstand-voltage semiconductor device 1 is realized.

Hereinafter, details of the polarization layer 60 of the semiconductor device 1 will be described.

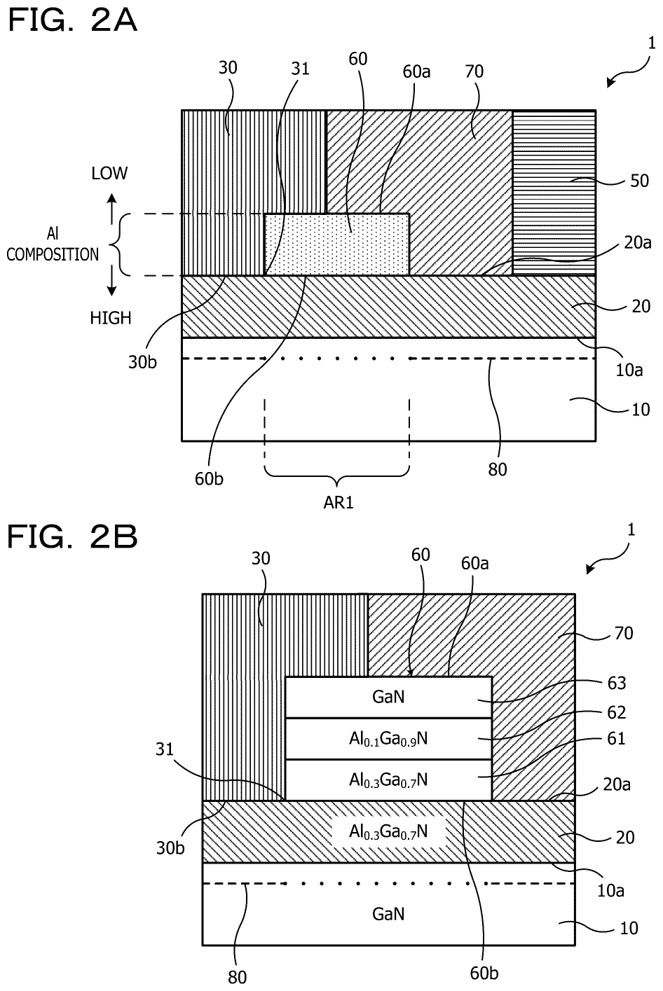

FIGS. 2A and 2B are diagrams for explaining a configuration example of the polarization layer of the semiconductor device according to the first embodiment. In each of FIGS. 2A and 2B, a main part cross-sectional diagram of an example of the semiconductor device is schematically illustrated.

As illustrated in FIG. 2A, the polarization layer 60 is provided between the gate electrode 30 and the drain electrode 50, on the surface 20a of the barrier layer 20. The polarization layer 60 extends from an end 31 of the gate electrode 30 on the side of the drain electrode 50 on the bottom surface 30b facing the barrier layer 20, toward the side of the drain electrode 50. In FIG. 2A, as an example, a configuration in which the polarization layer 60 extending from the end 31 of the gate electrode 30 does not reach the drain electrode 50, for example, a configuration in which the polarization layer 60 is separated from the drain electrode 50 is illustrated.

For example, on the side of the drain electrode 50, a part of the gate electrode 30 has a shape provided on the surface 60a on the opposite side to the surface 60b on the side of the barrier layer 20 of the polarization layer 60, for example, a shape covering the surface 60a. Note that, as illustrated in FIG. 1 above, the gate electrode 30 has a shape in which the insulation film 70 is interposed between a part thereof and the barrier layer 20, on the side of the source electrode 40. In other words, the gate electrode 30 has a so-called T-shape (FIG. 1). By adopting such a T-shape for the gate electrode 30, it is possible to increase a cross-sectional area and reduce a gate resistance while reducing a gate length. Furthermore, by adopting such a T-shape for the gate electrode 30, the electric field concentration can be alleviated by a field plate effect, and a withstand voltage can be increased.

The polarization layer 60 includes a nitride semiconductor containing Al. The polarization layer 60 has the inclined Al composition of which the Al composition decreases from the surface 60b on the side of the barrier layer 20 toward the surface 60a on the opposite side to the side of the barrier layer 20. In the polarization layer 60, the predetermined polarization occurs due to its inclined Al composition. Due to the polarization that occurs in the polarization layer 60, the 2DEG region 80 immediately below the polarization layer 60, for example, the 2DEG region 80 corresponding to a region AR1 illustrated in FIG. 2A is modulated, and electron concentration of the region AR1 is reduced.

Here, in FIG. 2B, a configuration example of the polarization layer 60, the barrier layer 20 where the polarization layer 60 is provided, and the channel layer 10 below the barrier layer 20 is illustrated. In this example, the barrier layer 20 of Al_{0.3}Ga_{0.7}N is provided on the side of the surface 10a of the GaN channel layer 10. Then, on the side of the surface 20a of the barrier layer 20, as the polarization layer 60, a layer including a first layer 61 of Al_{0.3}Ga_{0.7}N, a second layer 62 of Al_{0.1}Ga_{0.9}N, and a third layer 63 of GaN is provided. In this way, the polarization layer 60 can have a three-layer laminated structure of Al_{0.3}Ga_{0.7}N, Al_{0.1}Ga_{0.9}N, and GaN, of which the Al composition decreases from the surface 60b toward the surface 60a.

For example, an Al composition of the first layer 61 positioned on the most barrier layer 20 side of the polarization layer 60 can be the same as the Al composition of the barrier layer 20. For example, the Al composition of the surface 60b of the polarization layer 60 on the side of the barrier layer 20 can be the same as the Al composition of the surface 20a of the barrier layer 20 on the side of the polarization layer 60. In the example in FIG. 2B, both of the Al composition of the surface 60b of the polarization layer 60 and the Al composition of the surface 20a of the barrier layer 20 are set to 0.3. Furthermore, an Al composition of the third layer 63 positioned on an opposite side to the most barrier layer 20 side of the polarization layer 60 can be set to zero. In the example in FIG. 2B, GaN is used for the third layer 63. In this way, a part of the polarization layer 60 may include a layer that does not contain Al.

As illustrated in FIG. 2B, Al_{0.3}Ga_{0.7}N is used for both of the polarization layer 60 and the barrier layer 20, and the Al compositions of the surface 60b and the surface 20a are set to be the same. This suppresses lattice mismatch between the first layer 61 of the polarization layer 60 and the barrier layer 20 and occurrence of crystal defects due to the lattice mismatch. Furthermore, Al_{0.3}Ga_{0.7}N, Al_{0.1}Ga_{0.9}N, and GaN are used for the polarization layer 60, and the laminated structure is adopted in which the Al composition decreases from the surface 60b toward the surface 60a. This suppresses lattice mismatch between the first layer 61 and the second layer 62 and between the second layer 62 and the third layer 63 and the occurrence of the crystal defects due to the lattice mismatch.

Note that the Al composition of the barrier layer 20 and the Al compositions of the first layer 61, the second layer 62, and the third layer 63 of the polarization layer 60 are not limited to those illustrated in FIG. 2B. For example, the Al composition of the barrier layer 20 (surface 20a) and the Al composition of the first layer 61 (surface 60b) of the polarization layer 60 are not limited to 0.3 in the example and do not necessarily need to be the same as long as the occurrence of the lattice mismatch therebetween and the crystal defects can be suppressed. Furthermore, if the Al composition of the second layer 62 of the polarization layer 60 is lower than the Al composition of the first layer 61, the Al composition of the second layer 62 is not limited to 0.1 in the illustrated example and may be a value smaller than 0.1 or a value larger than 0.1, according to the Al composition of the first layer 61. Furthermore, if the Al composition of the third layer 63 of the polarization layer 60 is lower than the Al composition of the second layer 62, the third layer 63 may contain Al. Furthermore, the number of layers of the polarization layer 60 is not limited to three. If the polarization layer 60 has the inclined Al composition in which the Al composition decreases from the surface 60b toward the surface 60a, the number of layers of the polarization layer 60 may be two or equal to or more than four.

The polarization layer 60 illustrated in FIG. 2A has a structure having the inclined Al composition in which the Al composition decreases from the surface 60b toward the surface 60a, as a three-layer laminated structure including Al_{0.3}Ga_{0.7}N, Al_{0.1}Ga_{0.9}N, and GaN illustrated in FIG. 2B or the like. As a result, predetermined polarization occurs in the polarization layer 60.

Here, the polarization that occurs in the polarization layer 60 will be described.

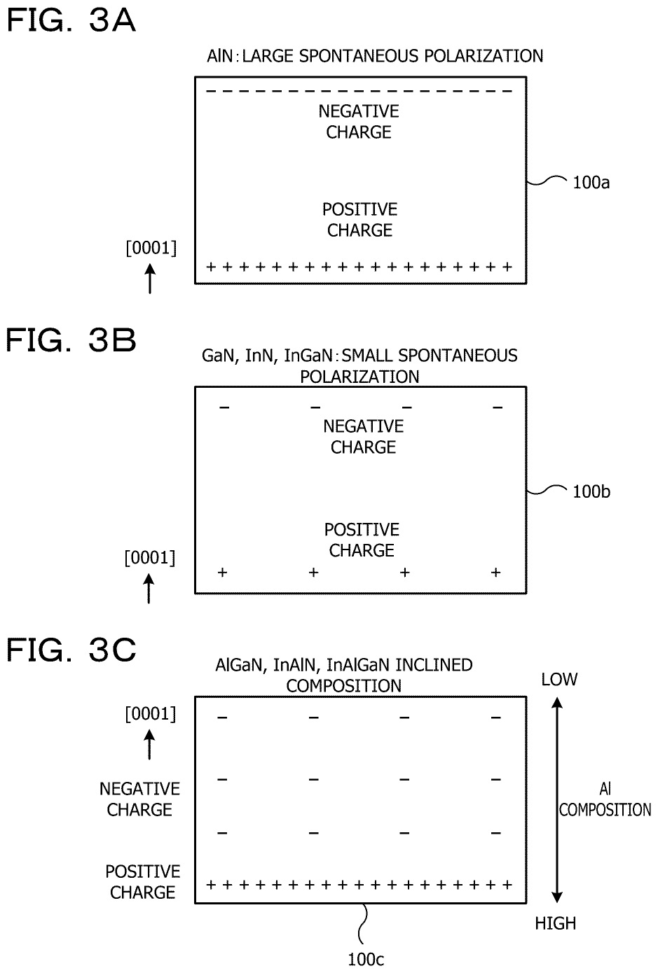

FIGS. 3A to 3C are diagrams for explaining a relationship between the Al composition of the nitride semiconductor and spontaneous polarization. FIG. 3A is a diagram schematically illustrating a state of spontaneous polarization of an AlN layer. FIG. 3B is a diagram schematically illustrating a state of spontaneous polarization of a layer of GaN or the like. FIG. 3C is a diagram schematically illustrating a state of spontaneous polarization of a layer of AlGaN or the like.

The nitride semiconductor has the spontaneous polarization along a [0001] direction (c axis). As an example, the spontaneous polarization of AlN is −0.081 C/m², the spontaneous polarization of GaN is −0.029 C/m², and the spontaneous polarization of indium nitride (InN) is −0.032 C/m². GaN and InN have the spontaneous polarizations about the same, while AlN has the spontaneous polarization stronger than that.

Regarding a polarization charge, in a case where the (0001) surface is used, for example, as illustrated in FIGS. 3A and 3B, a negative charge (illustrated as “−”) is generated on an upper end side of each of layers 100a and 100b of the nitride semiconductor, and a positive charge (illustrated as “+”) is generated on a lower end side. Since the spontaneous polarization of AlN is stronger than that of GaN, a charge amount generated in the layer 100a of AlN is larger than a charge amount generated in the layer 100b of GaN. Note that, since InN has the spontaneous polarization about the same as GaN, the same as GaN applies to InN and InGaN in which GaN is partially replaced with InN (FIG. 3B).

AlGaN in which GaN is partially replaced with AlN (or AlGaN in which AlN is partially replaced with GaN) has an intermediate charge amount of AlN and GaN, depending on its Al composition. At this time, if the Al composition of AlGaN is decreased toward an upper end of the layer, a relatively large negative charge amount generated on an upper end side of a lower layer portion in the layer is offset by a relatively small positive charge amount generated on a lower end side of an upper layer portion laminated directly above that. Therefore, in an entire layer including these layers, spontaneous polarization is generated as in a layer 100c illustrated in FIG. 3C, and a negative charge is generated in a wide range in the layer 100c. AlGaN in which the Al composition is decreased toward the upper end of the layer 100c exhibits properties of a p-type semiconductor (also referred to as “p-type semiconductivity”), by generating the negative charge in the wide range in the layer 100c in this way, for example, generating a negative fixed charge spreading in the layer 100c. The exhibition of the p-type semiconductivity by changing the Al composition in this way is also referred to as “polarization doping” or “polarization p-doping”.

Note that, since InN and GaN have the spontaneous polarizations about the same, the same as AlGaN applies to InAlN in which InN is partially replaced with AlN and InAlGaN in which InGaN, in which GaN is partially replaced with InN, is partially replaced with AlN.

In the semiconductor device 1 illustrated in FIGS. 1, 2A, and 2B above, the nitride semiconductor having the inclined Al composition that exhibits the p-type semiconductivity by decreasing the Al composition from the surface 60b toward the surface 60a is used for the polarization layer 60.

In the semiconductor device 1, for the polarization layer 60, AlGaN of which the Al composition decreases from the surface 60b toward the surface 60a may be used. For the polarization layer 60, InAlN of which the Al composition decreases from the surface 60b toward the surface 60a may be used. For the polarization layer 60, InAlGaN of which the Al composition decreases from the surface 60b toward the surface 60a may be used.

Furthermore, for the polarization layer 60, a combination of two or more of AlGaN, InAlN, and InAlGaN may be used, as long as the Al composition decreases from the surface 60b toward the surface 60a. An AlN layer may be included in the lowermost layer (side of surface 60b) of the polarization layer 60, and a layer of GaN, InN, or InGaN may be included in the uppermost layer (side of surface 60a) of the polarization layer 60.

For the polarization layer 60, a nitride semiconductor containing Al may be used, and a nitride semiconductor including a layer portion represented by a general formula InₓAl_{y}Ga_{1-(x+y)}N(0≤x≤1, 0≤y≤1, 0≤x+y≤1) can be used therein. The polarization layer 60 is formed on the side of the surface 20a of the barrier layer 20, using the MOVPE method or the like, so that the Al composition decreases from the surface 60b toward the surface 60a.

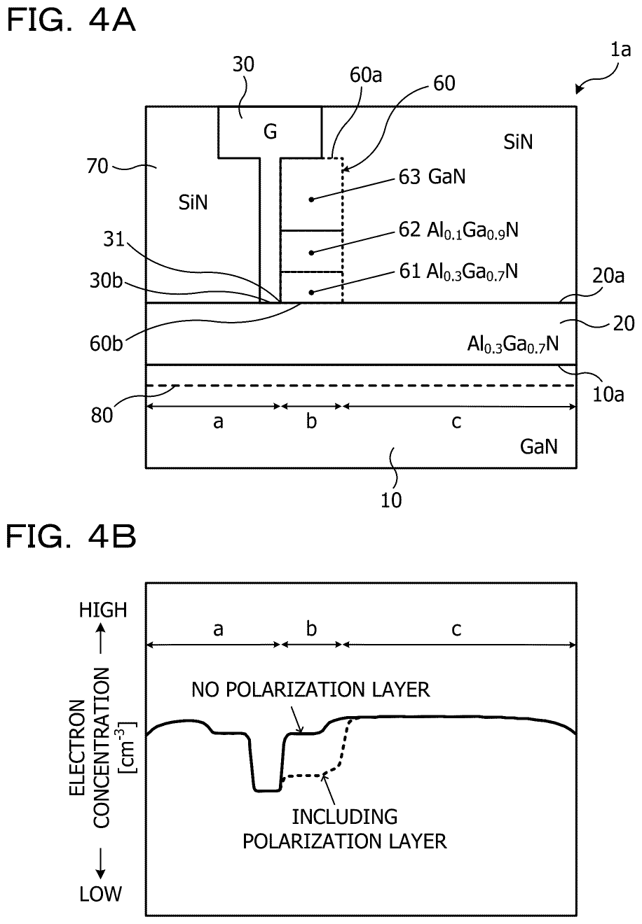

FIGS. 4A and 4B are diagrams for explaining an example of a simulation result of electron concentration in the semiconductor device. In FIG. 4A, an example of a semiconductor device model is illustrated. In FIG. 4B, an example of an electron concentration distribution is illustrated.

A semiconductor device model 1a illustrated in FIG. 4A includes the GaN channel layer 10, the barrier layer 20 of Al_{0.3}Ga_{0.7}N provided on a side of a surface 10a, and a gate electrode 30 (G) provided on a side of a surface 20a. The 2DEG region 80 is generated in the channel layer 10 on which the barrier layer 20 is laminated. One end portion of the gate electrode 30 on the side of the surface 20a of the barrier layer 20, the polarization layer 60 is provided. In FIG. 4A, the polarization layer 60 is indicated by a dotted line. The polarization layer 60 including the first layer 61 of Al_{0.3}Ga_{0.7}N, the second layer 62 of Al_{0.1}Ga_{0.9}N, and the third layer 63 of GaN is provided. The gate electrode 30 and the polarization layer 60 are covered with the insulation film 70 of SiN.

In FIG. 4B, an electron concentration distribution in the 2DEG region 80 in a case where the polarization layer 60 is not provided, in the semiconductor device model 1a is illustrated as a solid line, and an electron concentration distribution in the 2DEG region 80 in a case where the polarization layer 60 (illustrated as dotted line in FIG. 4A) is provided is illustrated as a dotted line. In regions a and c sandwiching a region b immediately below the end portion of the gate electrode 30, in the 2DEG region 80 illustrated in FIG. 4A, as illustrated in FIG. 4B, no significant difference in the electron concentration is recognized between a case where the polarization layer 60 is not provided in the end portion of the gate electrode 30 and a case where the polarization layer 60 is provided. On the other hand, in the region b immediately below the end portion of the gate electrode 30, in the 2DEG region 80 illustrated in FIG. 4A, as illustrated in FIG. 4B, the electron concentration in a case where the polarization layer 60 is provided (“including polarization layer” indicated by dotted line) decreases as compared with a case where the polarization layer 60 is not provided in the end portion of the gate electrode 30 (“no polarization layer” indicated by solid line).

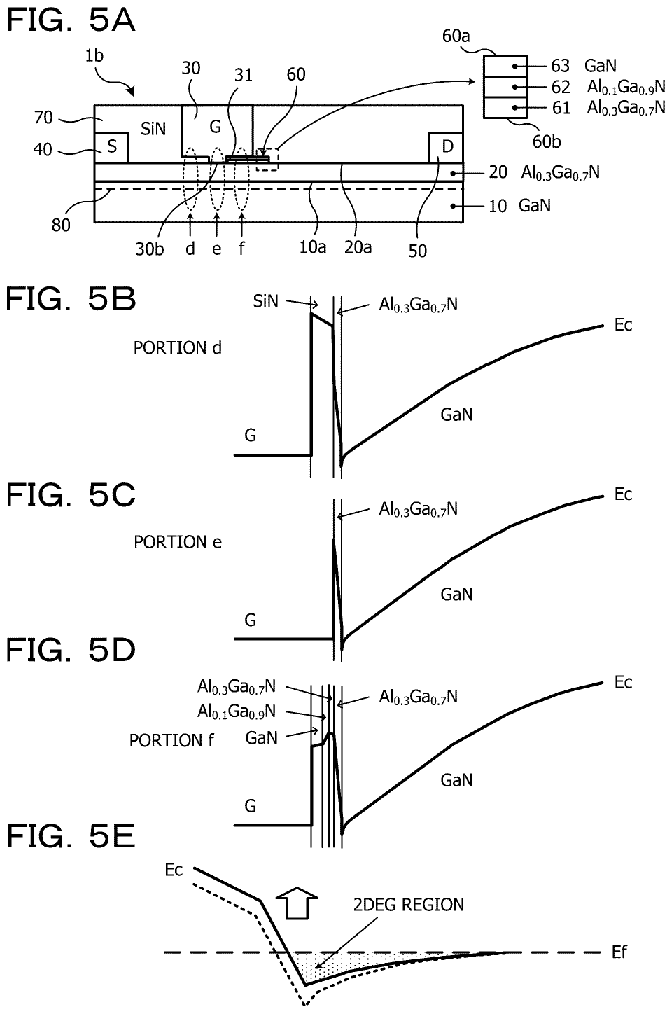

FIGS. 5A to 5E are diagrams for explaining an energy band of an example of the semiconductor device. In FIG. 5A, an example of a semiconductor device model is illustrated. In each of FIGS. 5B to 5D, an example of a conduction band of a predetermined portion of the semiconductor device model is illustrated. In FIG. 5E, an example of modulation of the 2DEG region is illustrated.

A semiconductor device model 1b illustrated in FIG. 5A includes the GaN channel layer 10, the barrier layer 20 of Al_{0.3}Ga_{0.7}N provided on the side of the surface 10a, the gate electrode 30 (G), the source electrode 40 (S), and the drain electrode 50 (D) provided on the side of the surface 20a. The 2DEG region 80 is generated in the channel layer 10 on which the barrier layer 20 is laminated. In the end portion of the gate electrode 30 on the side of the drain electrode 50, on the side of the surface 20a of the barrier layer 20, the polarization layer 60 is provided. The polarization layer 60 including the first layer 61 of Al_{0.3}Ga_{0.7}N, the second layer 62 of Al_{0.1}Ga_{0.9}N, and the third layer 63 of GaN is provided. The gate electrode 30, the source electrode 40, the drain electrode 50, and the polarization layer 60 are covered with the insulation film 70 of SiN.

An example of a conduction band Ec of a portion d corresponding to the end portion of the gate electrode 30 on the side of the source electrode 40, in the semiconductor device model 1b illustrated in FIG. 5A is illustrated in FIG. 5B. As illustrated in FIGS. 5A and 5B, the portion d has a structure in which the channel layer 10 of GaN, the barrier layer 20 of Al_{0.3}Ga_{0.7}N, and the insulation film 70 of SiN are laminated in order from the side of the channel layer 10, to reach the gate electrode 30.

An example of a conduction band Ec of a portion e corresponding to the gate electrode 30, in the semiconductor device model 1b illustrated in FIG. 5A is illustrated in FIG. 5C. As illustrated in FIGS. 5A and 5C, the portion e has a structure in which the channel layer 10 of GaN and the barrier layer 20 of Al_{0.3}Ga_{0.7}N are laminated in order from the side of the channel layer 10 to reach the gate electrode 30.

An example of a conduction band Ec of a portion f corresponding to the end portion of the gate electrode 30 on the side of the drain electrode 50, in the semiconductor device model 1b illustrated in FIG. 5A is illustrated in FIG. 5D. As illustrated in FIGS. 5A and 5D, the portion f has a structure in which the channel layer 10 of GaN, the barrier layer 20 of Al_{0.3}Ga_{0.7}N, the first layer 61 of the polarization layer 60 of Al_{0.3}Ga_{0.7}N, the second layer 62 of the polarization layer 60 of Al_{0.1}Ga_{0.9}N, and the third layer 63 of the polarization layer 60 of GaN are laminated in this order from the side of the channel layer 10 to reach the gate electrode 30.

In FIG. 5E, the conduction band Ec in the portion f (FIG. 5D) where the polarization layer 60 is provided, for example, the end portion of the gate electrode 30 on the side of the drain electrode 50 is illustrated as a solid line, and the conduction band Ec in a case where the polarization layer 60 is not provided in the portion f is illustrated as a dotted line, for comparison. In FIG. 5E, Ef represents a Fermi level. The conduction band Ec at a bonding interface between the channel layer 10 and the barrier layer 20 is lower than the Fermi level Ef (lower energy side) so that the 2DEG region 80 is generated in the channel layer 10 near the bonding interface with the barrier layer 20.

In the polarization layer 60 having the inclined Al composition, the negative fixed charge is generated in the layer (FIG. 3C), and the p-type semiconductivity is exhibited. The polarization layer 60 having the inclined Al composition that exhibits such p-type semiconductivity is provided in the end portion of the gate electrode 30 on the side of the drain electrode 50. As a result, in a case where the polarization layer 60 is provided (solid line in FIG. 5E), the conduction band Ec of the channel layer 10 is raised as compared with a case where the polarization layer 60 is not provided in the end portion of the gate electrode 30 on the side of the drain electrode 50 (dotted line in FIG. 5E).

For example, in a case where the polarization layer 60 is not provided in the end portion of the gate electrode 30 on the side of the drain electrode 50, as indicated by the dotted line in FIG. 5E, the conduction band Ec of the channel layer 10 is relatively low. On the other hand, in a case where the polarization layer 60 is provided in the end portion of the gate electrode 30 on the side of the drain electrode 50, due to the p-type semiconductivity of the polarization layer 60, as indicated by the solid line in FIG. 5E, the conduction band Ec of the channel layer 10 is raised (schematically illustrated as thick arrow in FIG. 5E) and becomes relatively high. By raising the conduction band Ec by the polarization layer 60, a potential lower than the Fermi level Ef is modulated to be raised, and the electron concentration in the 2DEG region 80 is reduced.

In the semiconductor device 1, by providing the polarization layer 60 in the end portion of the gate electrode 30 on the side of the drain electrode 50, the conduction band Ec immediately below the polarization layer 60 is raised by the polarization so as to modulate the 2DEG region 80, and the electron concentration in the 2DEG region 80 immediately below the polarization layer 60 is reduced.

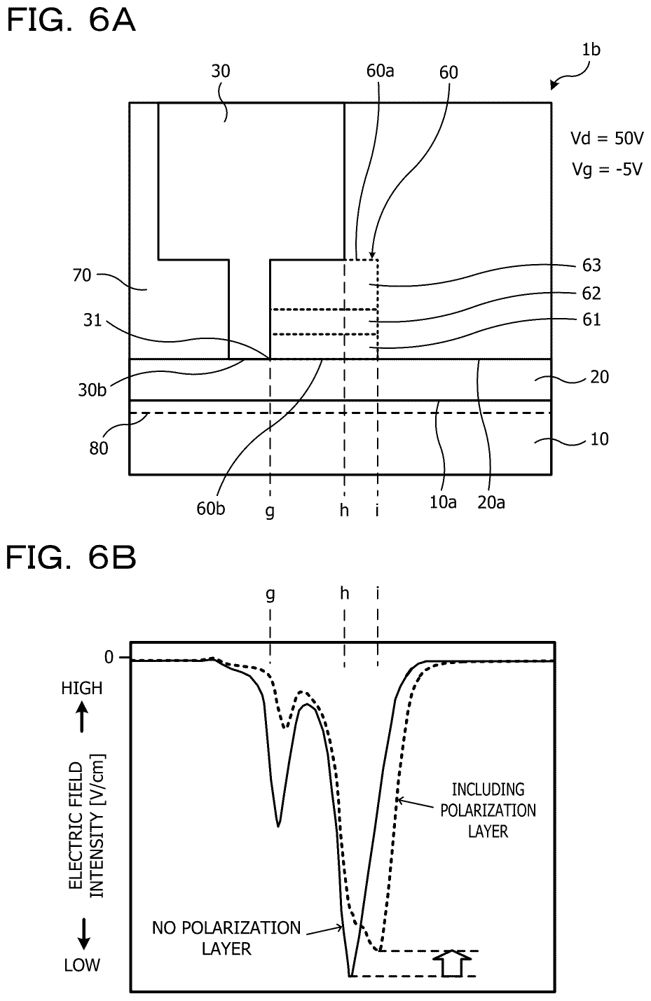

FIGS. 6A and 6B are diagrams for explaining an example of a simulation result of an electric field intensity in the semiconductor device. In FIG. 6A, an example of a semiconductor device model is illustrated. In FIG. 6B, an example of an electric field intensity distribution is illustrated.

In FIG. 6A, the vicinity of the gate electrode 30 of the semiconductor device model 1b is enlarged and illustrated. In FIG. 6A, the polarization layer 60 is illustrated as a dotted line. In FIG. 6A, a position g is a position corresponding to the end 31 of the gate electrode 30 on the side of the drain electrode 50 on the bottom surface 30b facing the barrier layer 20. A position h is a position corresponding to an end (side end surface) of the gate electrode 30 on the side of the drain electrode 50 and is an end of a portion covering the surface 60a of the polarization layer 60. A position i is a position corresponding to an end of the polarization layer 60 on the side of the drain electrode 50.

In FIG. 6B, an example of a simulation result of an electric field intensity distribution when a voltage (drain voltage) Vd applied to the drain electrode 50 is set to 50 V and a voltage (gate voltage) Vg applied to the gate electrode 30 is set to −5 V is illustrated. In FIG. 6B, the electric field intensity distribution in a case where the polarization layer 60 is not provided is illustrated as a solid line, and the electric field intensity distribution in a case where the polarization layer 60 (illustrated as dotted line in FIG. 6A) is provided is illustrated as a dotted line. In FIG. 6B, each of positions corresponding to the positions g, h, and i illustrated in FIG. 6A are illustrated.

As illustrated in FIG. 6B, in the electric field intensity distribution (“including polarization layer” illustrated as dotted line) in a case where the polarization layer 60 is provided, a concentration position of the electric field is shifted, and electric field concentration is alleviated, with respect to the electric field intensity distribution (“no polarization layer” illustrated as solid line) in a case where the polarization layer 60 is not provided.

From the above results, in the semiconductor device 1, by providing the polarization layer 60 in the end portion of the gate electrode 30 on the side of the drain electrode 50 and modulating the 2DEG region 80 immediately below the polarization layer 60 by the polarization, the electric field concentration near the end portion of the gate electrode 30 on the side of the drain electrode 50 is dispersed. In the semiconductor device 1, the electric field concentration near the end portion of the gate electrode 30 on the side of the drain electrode 50 is dispersed so that the electric field intensity is prevented from exceeding a limit of a material near the end portion. As a result, it is possible to prevent the semiconductor device 1 from being broken due to the electric field concentration. By providing the polarization layer 60, the high-withstand-voltage semiconductor device 1 is realized.

Next, a method for manufacturing the semiconductor device 1 having the above configuration will be described.

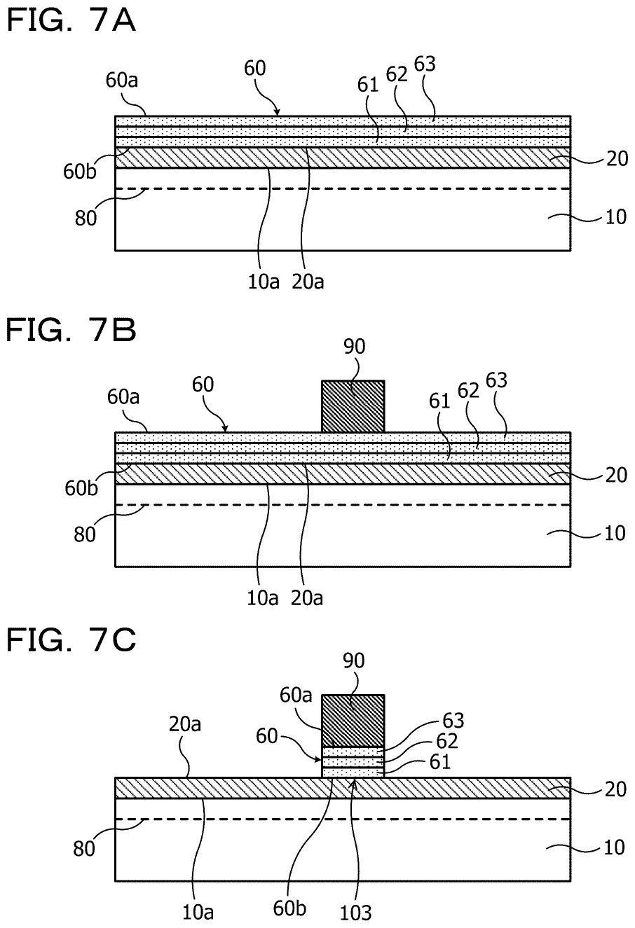

FIGS. 7A to 9C are diagrams for explaining an example of the method for manufacturing the semiconductor device according to the first embodiment. In each of FIGS. 7A to 7C, 8A to 8C, and 9A to 9C, a main part cross-sectional diagram of an example of each process for manufacturing the semiconductor device is schematically illustrated.

For example, as illustrated in FIG. 7A, a structure is prepared in which the barrier layer 20 is laminated on the surface 10a of the channel layer 10, and in addition, the first layer 61, the second layer 62, and the third layer 63 of the polarization layer 60 are laminated on the surface 20a of the barrier layer 20.

For the channel layer 10, for example, GaN is used. The channel layer 10 is grown using the MOVPE method or the like, on a predetermined base substrate including SiC, GaN, Si, or the like. A thickness of the channel layer 10 is set to 200 nm, for example.

For the barrier layer 20, for example, AlGaN is used. As an example, Al_{0.3}Ga_{0.7}N is used for the barrier layer 20. The barrier layer 20 is grown using the MOVPE method or the like, on the surface 10a ((0001) surface) of the channel layer 10. A thickness of the barrier layer 20 is set to a range from nine nm to 25 nm, for example.

On the channel layer 10, the barrier layer 20 using a nitride semiconductor having a bandgap different from the channel layer 10 is laminated, and the 2DEG region 80 is generated near the bonding interface of the channel layer 10 with the barrier layer 20.

In this example, as the polarization layer 60, a layer having the three-layer laminated structure including the first layer 61, the second layer 62, and the third layer 63 is provided.

For the first layer 61, for example, AlGaN is used. For the first layer 61, AlGaN having an Al composition same as or close to that of AlGaN used for the barrier layer 20 (AlGaN on surface 20a of barrier layer 20) is used. As an example, Al_{0.3}Ga_{0.7}N having the same Al composition as the barrier layer 20 is used for the first layer 61. For example, the first layer 61 is grown using the MOVPE method or the like, on the surface 20a ((0001) surface) of the barrier layer 20. When the Al composition of the first layer 61 is set to be the same as or closer to the Al composition of the barrier layer 20, the occurrence of the lattice mismatch between the first layer 61 and the barrier layer 20 and the crystal defects in the first layer 61 is suppressed.

For the second layer 62, for example, AlGaN is used. For the second layer 62, AlGaN having an Al composition lower than AlGaN used for the first layer 61 is used. As an example, Al_{0.1}Ga_{0.9}N is used for the second layer 62. The second layer 62 is grown using the MOVPE method or the like, on the first layer 61 ((0001) surface). When the Al composition of the second layer 62 is set to be lower than the Al composition of the first layer 61 and to be closer to the Al composition, the occurrence of the lattice mismatch between the second layer 62 and the first layer 61 and the crystal defects in the second layer 62 is suppressed.

For the third layer 63, for example, GaN is used. For the third layer 63, GaN having an Al composition lower than AlGaN used for the second layer 62 is used. For the third layer 63, AlGaN having the Al composition lower than AlGaN used for the second layer 62 may be used. The third layer 63 is grown using the MOVPE method or the like, on the second layer 62 ((0001) surface). When the Al composition of the third layer 63 (zero at the time of GaN) is set to be lower than the Al composition of the second layer 62 and to be closer to the Al composition, the occurrence of the lattice mismatch between the third layer 63 and the second layer 62 and the crystal defects in the third layer 63 is suppressed.

With the three-layer laminated structure including the first layer 61, the second layer 62, and the third layer 63, the polarization layer 60 having the inclined Al composition is formed in which the Al composition decreases from the surface 60b on the side of the barrier layer 20 toward the surface 60a on the opposite side to the side of the barrier layer 20.

A thickness of the polarization layer 60 including the first layer 61, the second layer 62, and the third layer 63 is set to be equal to or less than 40 nm, for example. A thickness of each of the first layer 61, the second layer 62, and the third layer 63 may be different from each other or may be the same as each other. The thickness of each of the first layer 61, the second layer 62, and the third layer 63 may be set, based on the Al composition of each layer, the lattice relaxation according to the thickness at the time of growth, or the like. In a case where the thickness (total thickness) of the polarization layer 60 exceeds 40 nm, there is a possibility that workings of the layer relaxation increase and polarization that can sufficiently modulate the 2DEG region 80 does not occur in the polarization layer 60.

Note that, in a case where the same nitride semiconductor is used for the first layer 61 and the barrier layer 20 (at least surface layer portion on side of surface 20a), at the time when the barrier layer 20 is grown by using the MOVPE method or the like, a portion caused to function as the first layer 61 may be grown following a portion caused to function as the barrier layer 20.

Here, the polarization layer 60 having the three-layer laminated structure including the first layer 61, the second layer 62, and the third layer 63 is described as an example. However, in a case of the inclined Al composition in which the Al composition decreases from the surface 60b toward the surface 60a, the polarization layer 60 having a laminated structure including two layers or four or more layers may be provided.

The polarization layer 60 formed on the barrier layer 20 as illustrated in FIG. 7A is patterned by etching using a mask 90 as illustrated in FIGS. 7B and 7C.

For example, as illustrated in FIG. 7B, in a predetermined region on the polarization layer 60, the mask 90 is formed. As an example, the mask 90 of SiN is formed, using a chemical vapor deposition (CVD) method or the like. The mask 90 is formed on the polarization layer 60 and in a region between the gate electrode 30 and the drain electrode 50 formed as described layer. For example, the mask 90 is formed in a region to be the end portion of the gate electrode 30 on the side of the drain electrode 50.

Then, as illustrated in FIG. 7C, the mask 90 formed in the predetermined region on the polarization layer 60 is used to remove a portion of the third layer 63, the second layer 62, and the first layer 61 of the polarization layer 60 exposed from the mask 90 is removed by etching. For example, chlorine-based gas is used, and the third layer 63, the second layer 62, and the first layer 61 of the polarization layer 60 are removed by dry etching. As a result, in a predetermined region on the barrier layer 20 illustrated in FIG. 7C, the polarization layer 60 patterned by etching is formed. The polarization layer 60 is formed to remain in a region 103 on the side of the surface 20a of the barrier layer 20, by patterning.

Note that, in a case where the same nitride semiconductor is used for the first layer 61 and the barrier layer 20, the first layer 61 is formed in a portion remained by patterning, by etching a surface layer portion of the nitride semiconductor.

After patterning by etching the polarization layer 60, the mask 90 is removed. For example, the mask 90 is removed by wet etching using hydrofluoric acid or the like.

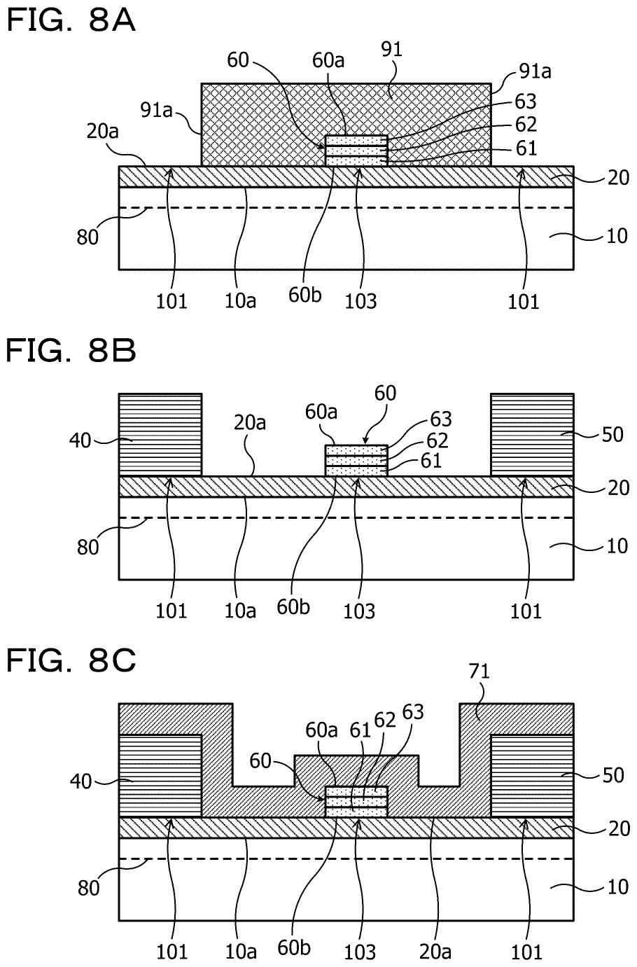

After the mask 90 is removed, as illustrated in FIG. 8A, a resist 91 is formed. As the resist 91, the resist 91 having an opening portion 91a that is formed in a region corresponding to the source electrode 40 and the drain electrode 50 formed as described later. The opening portion 91a is formed in a region 101 on the side of the surface 20a of the barrier layer 20 that is a region 101 where the source electrode 40 and the drain electrode 50 are formed.

After the resist 91 is formed, a metal material is deposited on the resist 91 and in the opening portion 91a, by the vapor deposition method. As an example, a laminated body including Ta or Ti and Al provided thereon is formed by deposition. After the deposition, the resist 91 and the metal material deposited thereon are removed by a lift-off technique. As a result, as illustrated in FIG. 8B, the source electrode 40 and the drain electrode 50 are formed on the barrier layer 20 (region 101 on side of surface 20a of barrier layer 20).

Thereafter, predetermined heat treatment is performed, and ohmic connection between the source electrode 40 and the drain electrode 50 is established. As a result, the source electrode 40 and the drain electrode 50 that function as ohmic electrodes are formed.

After the formation of the source electrode 40 and the drain electrode 50, as illustrated in FIG. 8C, a passivation film 71 is formed. For example, the passivation film 71 of SiN is formed, using the CVD method or the like. The passivation film 71 is formed to cover, for example, the barrier layer 20, the polarization layer 60, the source electrode 40, and the drain electrode 50.

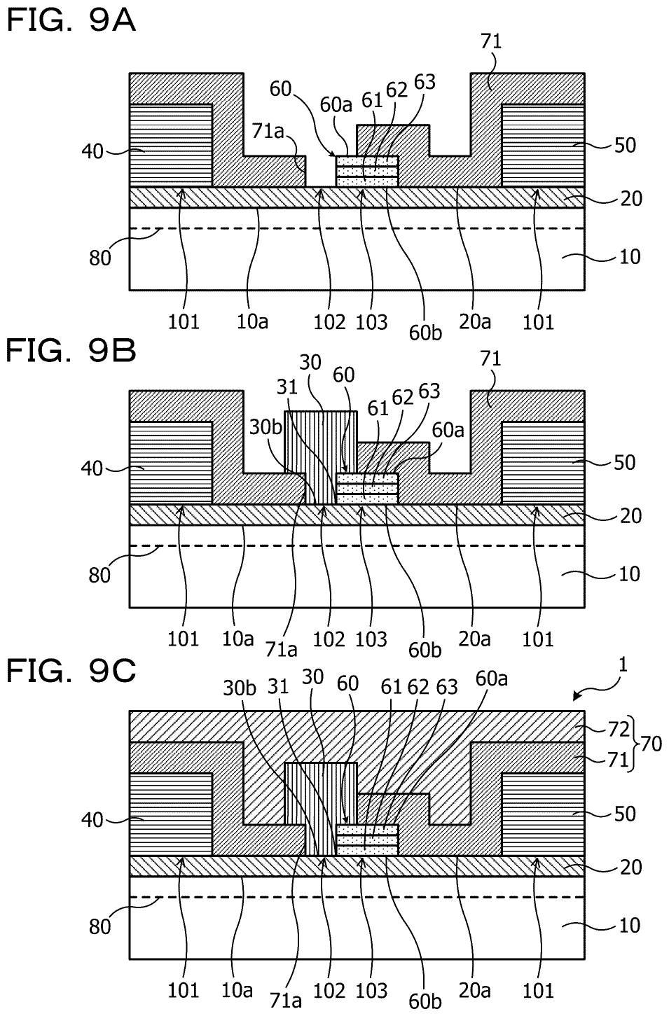

After the formation of the passivation film 71, as illustrated in FIG. 9A, an opening portion 71a is formed in a predetermined region of the passivation film 71. The opening portion 71a of the passivation film 71 is formed in a region corresponding to the gate electrode 30 formed as described later. The opening portion 71a is formed so that a part of the barrier layer 20 (surface 20a thereof) and a part of the polarization layer 60 (surface 60a thereof) are exposed. The opening portion 71a is formed in a region 102 on the side of the surface 20a of the barrier layer 20 that is a region 102 where the gate electrode 30 is formed.

After the formation of the opening portion 71a of the passivation film 71, as illustrated in FIG. 9B, the gate electrode 30 is formed in the opening portion 71a. For example, the metal material of the gate electrode 30 is deposited on the opening portion 71a, using a lithography technique, a deposition technique, and the lift-off technique. As an example, a laminated body including Ni and Au provided thereon is deposited, and the gate electrode 30 is formed by the lift-off technique. As a result, in the opening portion 71a of the passivation film 71 (region 102 on side of surface 20a of barrier layer 20), the gate electrode 30 that functions as a Schottky electrode is formed.

The gate electrode 30 is formed to cover the barrier layer 20 and the polarization layer 60 in the opening portion 71a. A part of the gate electrode 30 is provided on the surface 60a of the polarization layer 60. The polarization layer 60 extends from an end 31 of the gate electrode 30 on the side of the drain electrode 50 on the bottom surface 30b facing the barrier layer 20, toward the side of the drain electrode 50. As a result, a state is obtained where the polarization layer 60 is provided in the end portion of the gate electrode 30 on the side of the drain electrode 50.

With the above method, it can be said that the source electrode 40, the drain electrode 50, and the gate electrode 30 are formed so that the polarization layer 60 is provided between the gate electrode 30 and the drain electrode 50, from among between the gate electrode 30 and the source electrode 40 and between the gate electrode 30 and the drain electrode 50.

Here, the region 101 where the drain electrode 50 is formed, on the side of the surface 20a of the barrier layer 20 is also referred to as a “first region”. The region 102 facing the region 101 where the drain electrode 50 is formed, on the side of the surface 20a of the barrier layer 20, that is, the region 102 where the gate electrode 30 is formed is also referred to as a “second region”. The region 103, between the region 101 where the drain electrode 50 is formed and the region 102 where the gate electrode 30 is formed, where the polarization layer 60 is formed (remaining by patterning), on the side of the surface 20a of the barrier layer 20 is also referred to as a “third region”.

In the above method, in the process for removing the polarization layer 60 (FIGS. 7B and 7C), it can be said that the polarization layer 60 in the region 101 (first region) where the drain electrode 50 is formed and the region 102 (second region) where the gate electrode 30 is formed, on the side of the surface 20a of the barrier layer 20 is removed. Then, in the process for forming the drain electrode 50 (FIGS. 8A and 8B), it can be said that the drain electrode 50 is formed in the region 101 (first region) where the polarization layer 60 is removed. Moreover, in the process for forming the gate electrode 30 (FIGS. 9A and 9B), it can be said that the gate electrode 30 is formed in the region 102 (second region) where the polarization layer 60 is removed.

After the formation of the gate electrode 30, as illustrated in FIG. 9C, an interlayer insulation film 72 is formed. For the interlayer insulation film 72, various insulating materials such as silicon oxide (SiO) or SiN can be used. For example, for the interlayer insulation film 72, the same type of insulating material as the passivation film 71 is used. For example, the interlayer insulation film 72 of SiN is formed, using the CVD method or the like. The interlayer insulation film 72 is formed to cover the passivation film 71 and the gate electrode 30, for example. By the laminated body including the passivation film 71 and the interlayer insulation film 72, the insulation film 70 as illustrated in FIG. 1 or the like above is formed.

Through the above process, the semiconductor device 1 having the configuration illustrated in FIG. 9C is manufactured.

Note that, in the above manufacturing process, the cap layer of GaN or the like may be formed on the surface 20a of the barrier layer 20. Furthermore, between the channel layer 10 and the barrier layer 20, the spacer layer of AlGaN, InGaN, or the like may be formed. Furthermore, between the channel layer 10 and the base substrate not illustrated, various layers including the initial layer, the buffer layer, the back barrier layer, or the like may be formed.

Furthermore, in the above manufacturing process, at the time when the source electrode 40 and the drain electrode 50 are formed, if the ohmic connection is realized by forming these metal materials, it does not necessarily need to perform the above heat treatment. At the time when the gate electrode 30 is formed, after the formation of the metal material, the heat treatment may be further performed. Furthermore, the gate electrode 30 may be provided on the side of the surface 20a of the barrier layer 20 via a gate insulation film (not illustrated) using an oxide, a nitride, an oxynitride, or the like and have an MIS-type gate structure.

### Second Embodiment

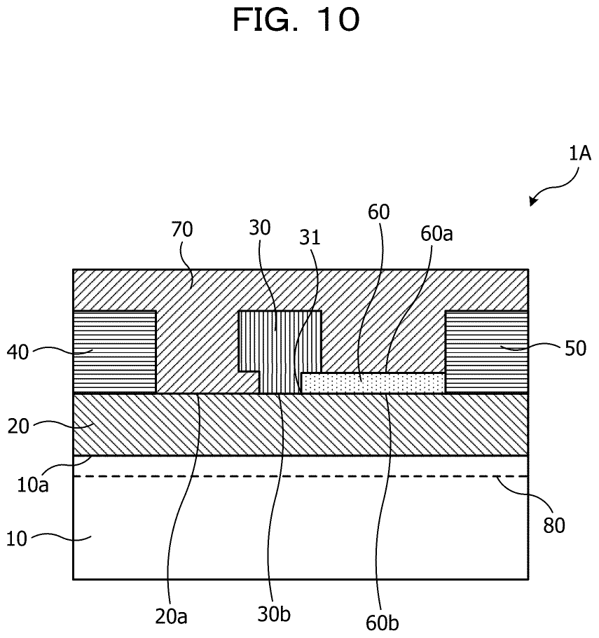

FIG. 10 is a diagram for explaining an example of a semiconductor device according to a second embodiment. In FIG. 10, a main part cross-sectional diagram of an example of the semiconductor device is schematically illustrated.

A semiconductor device 1A illustrated in FIG. 10 is an example of a HEMT. The semiconductor device 1A has a configuration in which a polarization layer 60 extending from an end 31 of a gate electrode 30 on a side of a drain electrode 50 on a bottom surface 30b toward the side of the drain electrode 50 reaches the drain electrode 50. For example, in the semiconductor device 1A, the polarization layer 60 is provided so as to be in contact with the drain electrode 50. The semiconductor device 1A is different from the semiconductor device 1 (FIG. 1 or the like) described in the first embodiment above, in that the semiconductor device 1A has such a configuration.

The polarization layer 60 is set to have an inclined Al composition in which an Al composition decreases from a surface 60a on a side of a barrier layer 20 toward a surface 60a on an opposite side. In the semiconductor device 1A, the polarization layer 60 having such an inclined Al composition is provided to extend from the end portion of the gate electrode 30 on the side of the drain electrode 50 to the drain electrode 50.

In the polarization layer 60, polarization that exhibits p-type semiconductivity occurs due to its inclined Al composition. Due to the polarization that occurs in the polarization layer 60, a conduction band immediately below the polarization layer 60 is raised, a 2DEG region 80 is modulated, and electron concentration in the 2DEG region 80 immediately below the polarization layer 60 is reduced. In the semiconductor device 1A, the polarization layer 60 is provided in a region from the gate electrode 30 to the drain electrode 50. Therefore, in the semiconductor device 1A, without limiting to the end portion of the gate electrode 30 on the side of the drain electrode 50, the electron concentration in the 2DEG region 80 is reduced, across a wider range from the gate electrode 30 to the drain electrode 50. As a result, an electric field of the gate electrode 30 on the side of the drain electrode 50 is alleviated. As a result, a material in the region from the gate electrode 30 to the drain electrode 50 is prevented from reaching a breakdown field, and the semiconductor device 1A is prevented from being broken. By providing the polarization layer 60, the high-withstand-voltage semiconductor device 1A is realized.

As in the semiconductor device 1A, even if the polarization layer 60 is provided in the region from the gate electrode 30 to the drain electrode 50 and the electron concentration of the region is reduced, deterioration in operation performance of the semiconductor device 1A is suppressed, with respect to the semiconductor device 1 described in the above first embodiment. For example, the deterioration in the operation performance of the semiconductor device 1A such as an increase in a resistance and a decrease in an output due to that for the semiconductor device 1 described above is suppressed. This is because, if the electron concentration immediately below the polarization layer 60 provided in the region from the gate electrode 30 to the drain electrode 50 in the semiconductor device 1A does not fall below the electron concentration immediately below the polarization layer 60 provided in the end portion of the gate electrode 30 on the side of the drain electrode 50 in the above semiconductor device 1, this does not cause a resistance.

According to the semiconductor device 1A, it is possible to alleviate the electric field of the region in the wider range from the gate electrode 30 to the drain electrode 50, while suppressing the deterioration in the operation performance, to prevent the material in the region from reaching the breakdown field, and to prevent the semiconductor device 1A from being broken.

In the manufacturing of the semiconductor device 1A having the above configuration, in the process for removing the polarization layer 60 illustrated in FIGS. 7B and 7C above, the region covered with the mask 90 and the region remained by etching using the mask 90, of the polarization layer 60 are changed. For example, the mask 90 is formed and etched so as to extend the polarization layer 60 between the region 101 where the drain electrode 50 is formed (FIGS. 8A and 8B) and the region 102 where the gate electrode 30 is formed (FIGS. 9A and 9B), on the side of the surface 20a of the barrier layer 20. The semiconductor device 1A can be manufactured according to the example of the manufacturing method described about the above semiconductor device 1, except for such a change.

The first and second embodiments have been described above.

The semiconductor devices 1, 1A, or the like described above can be applied to various electronic devices. As examples, cases in which the semiconductor device having the above configuration is applied to a semiconductor package, a power factor correction circuit, a power supply device, and an amplifier will be described below.

### Third Embodiment

Here, an application example of a semiconductor device having the above configuration to a semiconductor package will be described as a third embodiment.

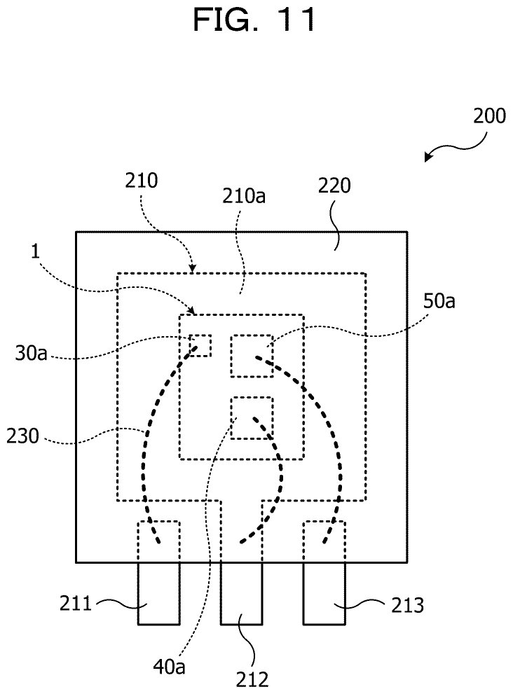

FIG. 11 is a diagram for explaining an example of the semiconductor package according to the third embodiment. FIG. 11 schematically illustrates a plan view of a main part of an example of the semiconductor package.

A semiconductor package 200 illustrated in FIG. 11 is an example of a discrete package. The semiconductor package 200 includes, for example, the semiconductor device 1 (FIG. 1 or the like) as described in the above first embodiment, a lead frame 210 on which the semiconductor device 1 is mounted, and a resin 220 that seals the semiconductor device 1 and the lead frame 210.

For example, the semiconductor device 1 is mounted on a die pad 210a of the lead frame 210, using a die attach material or the like (not illustrated). In the semiconductor device 1, a pad 30a coupled to the above gate electrode 30, a pad 40a coupled to a source electrode 40, and a pad 50a coupled to a drain electrode 50 are provided. The pad 30a, the pad 40a, and the pad 50a are respectively coupled to a gate lead 211, a source lead 212, and a drain lead 213 of the lead frame 210, using a wire 230 of Au, Al, or the like. The lead frame 210, the semiconductor device 1 mounted thereon, and a wire 230 coupling those are sealed with the resin 220 so as to expose a part of each of the gate lead 211, the source lead 212, and the drain lead 213.

In the semiconductor device 1, an external coupling electrode coupled to the source electrode 40 may be provided on a surface on an opposite side to a surface where the pad 30a coupled to the gate electrode 30 and the pad 50a coupled to the drain electrode 50 are provided. The external coupling electrode may be coupled to the die pad 210a connected to the source lead 212 using a conductive bonding material such as solder.

For example, the semiconductor device 1 described in the above first embodiment is used, and the semiconductor package 200 having such a configuration is obtained.

As described above, in the semiconductor device 1, a polarization layer 60 is provided that extends from an end portion of the gate electrode 30 on a side of the drain electrode 50 toward the side of the drain electrode 50. The polarization layer 60 has an inclined Al composition in which an Al composition decreases from a surface 60b on a side of a barrier layer 20 toward a surface 60a on an opposite side. Due to polarization that occurs in the polarization layer 60, electron concentration in a 2DEG region 80 immediately below the polarization layer 60 is reduced. As a result, electric field concentration of the gate electrode 30 on the side of the drain electrode 50 and breakdown caused by the electric field concentration are suppressed. With the polarization layer 60, the high-withstand-voltage semiconductor device 1 is realized. Such a semiconductor device 1 is used, and the semiconductor package 200 with high performance is realized.

Here, the semiconductor device 1 is described as an example.

However, it is possible to similarly obtain the semiconductor package using other semiconductor devices 1A or the like.

### Fourth Embodiment

Here, an application example of a semiconductor device having a configuration as described above to a power factor correction circuit will be described as a fourth embodiment.

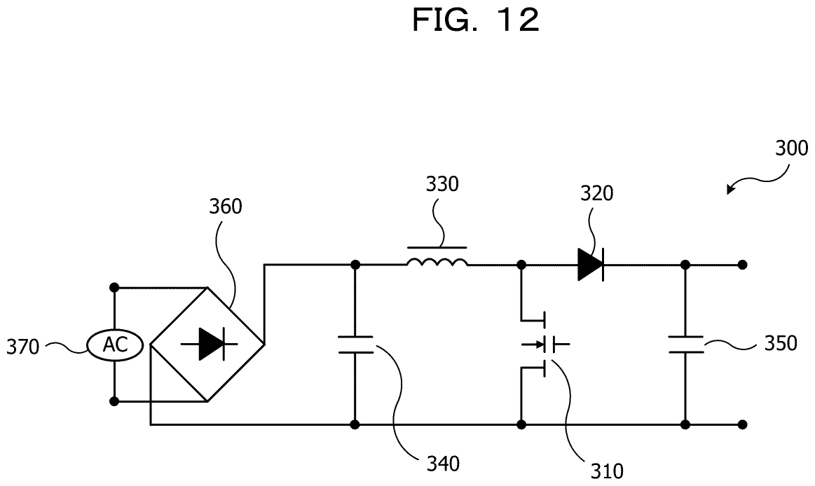

FIG. 12 is a diagram for explaining an example of the power factor correction circuit according to the fourth embodiment. FIG. 12 illustrates an equivalent circuit diagram of an example of the power factor correction circuit.

A power factor correction (PFC) circuit 300 illustrated in FIG. 12 includes a switch element 310, a diode 320, a choke coil 330, a capacitor 340, a capacitor 350, a diode bridge 360, and an alternating current power supply 370 (AC).

In the PFC circuit 300, a drain electrode of the switch element 310 is coupled to an anode terminal of the diode 320 and one terminal of the choke coil 330. A source electrode of the switch element 310 is coupled to one terminal of the capacitor 340 and one terminal of the capacitor 350. Another terminal of the capacitor 340 and another terminal of the choke coil 330 are coupled. Another terminal of the capacitor 350 and a cathode terminal of the diode 320 are coupled. Furthermore, a gate driver is coupled to a gate electrode of the switch element 310. The alternating current power supply 370 is coupled between both terminals of the capacitor 340 via the diode bridge 360, and a direct current power supply (DC) is extracted from both terminals of the capacitor 350.

For example, the above semiconductor devices 1, 1A, and the like are used for the switch element 310 of the PFC circuit 300 having such a configuration.

As described above, in the semiconductor devices 1, 1A, or the like, a polarization layer 60 that extends from an end portion of a gate electrode 30 on a side of a drain electrode 50 toward the side of the drain electrode 50 is provided. The polarization layer 60 has an inclined Al composition in which an Al composition decreases from a surface 60b on a side of a barrier layer 20 toward a surface 60a on an opposite side. Due to polarization that occurs in the polarization layer 60, electron concentration in a 2DEG region 80 immediately below the polarization layer 60 is reduced. As a result, electric field concentration of the gate electrode 30 on the side of the drain electrode 50 and breakdown caused by the electric field concentration are suppressed. With the polarization layer 60, the high-withstand-voltage semiconductor devices 1, 1A, or the like are realized. Such semiconductor devices 1, 1A, or the like is used, and the PFC circuit 300 with high performance is realized.

### Fifth Embodiment

Here, an application example of a semiconductor device having a configuration as described above to a power supply device will be described as a fifth embodiment.

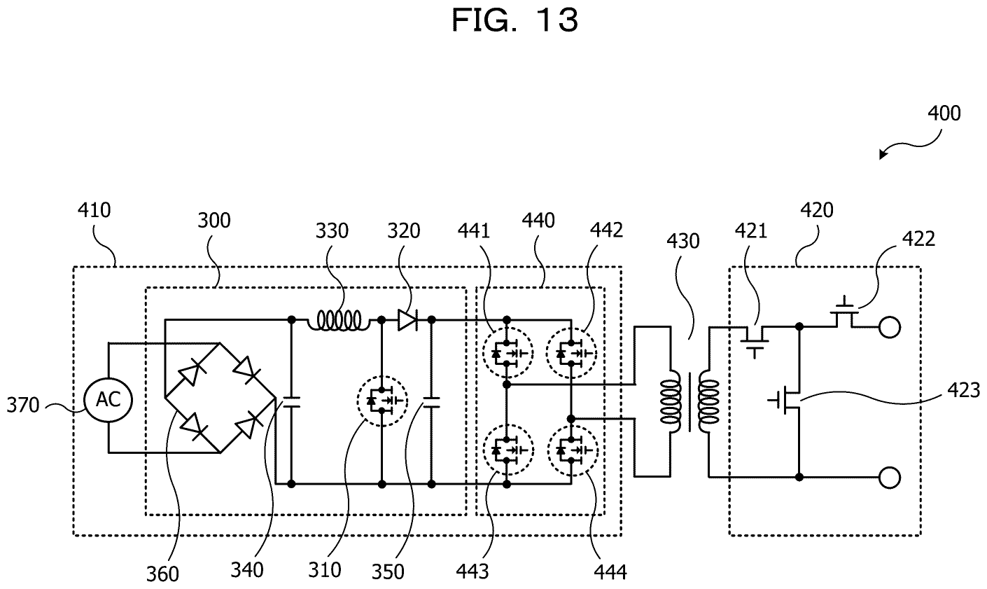

FIG. 13 is a diagram for explaining an example of the power supply device according to the fifth embodiment. FIG. 13 illustrates an equivalent circuit diagram of an example of the power supply device.

A power supply device 400 illustrated in FIG. 13 includes a primary-side circuit 410, a secondary-side circuit 420, and a transformer 430 provided between the primary-side circuit 410 and the secondary-side circuit 420.

The primary-side circuit 410 includes the PFC circuit 300 as described in the above fourth embodiment, and an inverter circuit, for example, a full-bridge inverter circuit 440 coupled between both terminals of a capacitor 350 of the PFC circuit 300. The full-bridge inverter circuit 440 includes a plurality of (here, four as an example) switch elements 441, 442, 443, and 444.

The secondary-side circuit 420 includes a plurality of (here, three as an example) switch elements 421, 422, and 423.

For example, the semiconductor devices 1, 1A, or the like described above is used for the switch element 310 of the PFC circuit 300 included in the primary-side circuit 410 and the switch elements 441 to 444 of the full-bridge inverter circuit 440 of the power supply device 400 having such a configuration. For example, for the switch elements 421 to 423 of the secondary-side circuit 420 of the power supply device 400, a normal MIS-type electric field effect transistor using Si is used.

As described above, in the semiconductor devices 1, 1A, or the like, a polarization layer 60 that extends from an end portion of a gate electrode 30 on a side of a drain electrode 50 toward the side of the drain electrode 50 is provided. The polarization layer 60 has an inclined Al composition in which an Al composition decreases from a surface 60b on a side of a barrier layer 20 toward a surface 60a on an opposite side. Due to polarization that occurs in the polarization layer 60, electron concentration in a 2DEG region 80 immediately below the polarization layer 60 is reduced. As a result, electric field concentration of the gate electrode 30 on the side of the drain electrode 50 and breakdown caused by the electric field concentration are suppressed. With the polarization layer 60, the high-withstand-voltage semiconductor devices 1, 1A, or the like are realized. Such semiconductor devices 1, 1A, or the like is used, and the power supply device 400 with high performance is realized.

### Sixth Embodiment

Here, an application example of a semiconductor device having a configuration as described above to an amplifier will be described as a sixth embodiment.

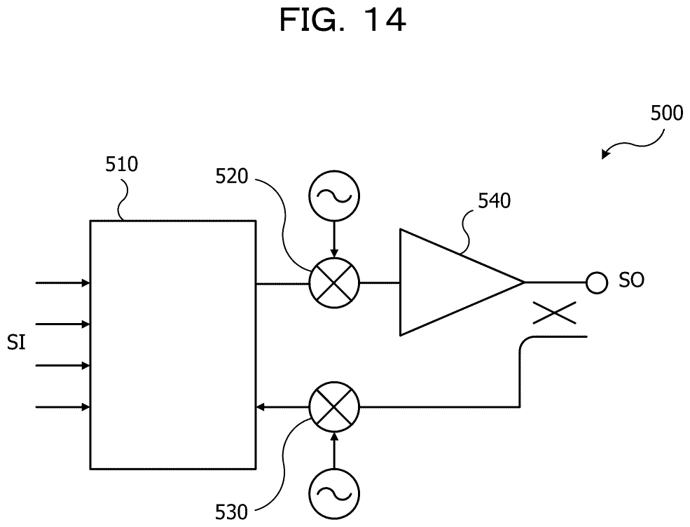

FIG. 14 is a diagram for explaining an example of the amplifier according to the sixth embodiment. FIG. 14 illustrates an equivalent circuit diagram of an example of the amplifier.

An amplifier 500 illustrated in FIG. 14 includes a digital predistortion circuit 510, a mixer 520, a mixer 530, and a power amplifier 540.

The digital predistortion circuit 510 compensates for nonlinear distortion of an input signal. The mixer 520 mixes an input signal SI compensated for its nonlinear distortion with an alternating current signal. The power amplifier 540 amplifies a signal obtained by mixing the input signal SI with the alternating current signal. The amplifier 500 can, for example, mix an output signal SO with the alternating current signal using the mixer 530 by switching a switch and can send the mixed signal to the digital predistortion circuit 510. The amplifier 500 can be used as a high-frequency amplifier or a high-output amplifier.

The above semiconductor devices 1, 1A, or the like is used for the power amplifier 540 of the amplifier 500 having such a configuration.

As described above, in the semiconductor devices 1, 1A, or the like, a polarization layer 60 that extends from an end portion of a gate electrode 30 on a side of a drain electrode 50 toward the side of the drain electrode 50 is provided. The polarization layer 60 has an inclined Al composition in which an Al composition decreases from a surface 60b on a side of a barrier layer 20 toward a surface 60a on an opposite side. Due to polarization that occurs in the polarization layer 60, electron concentration in a 2DEG region 80 immediately below the polarization layer 60 is reduced. As a result, electric field concentration of the gate electrode 30 on the side of the drain electrode 50 and breakdown caused by the electric field concentration are suppressed. With the polarization layer 60, the high-withstand-voltage semiconductor devices 1, 1A, or the like are realized. Such semiconductor devices 1, 1A, or the like is used, and the amplifier 500 with high performance is realized.

Various electronic devices to which the above semiconductor devices 1, 1A, or the like is applied (semiconductor package 200, PFC circuit 300, power supply device 400, amplifier 500, and the like described in third to sixth embodiments above) can be mounted on various types of electronic equipment or electronic devices. For example, the electronic devices can be mounted on various types of electronic equipment or electronic devices such as a computer (personal computer, supercomputer, server, or the like), a smartphone, a mobile phone, a tablet terminal, a sensor, a camera, an audio apparatus, a measuring device, an inspection device, a manufacturing device, a transmitter, a receiver, or a radar device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a channel layer that includes a first nitride semiconductor;
a barrier layer that is provided on a first surface side of the channel layer and includes a second nitride semiconductor;
a source electrode and a drain electrode provided on a second surface side opposite to the channel layer side, of the barrier layer;
a gate electrode provided between the source electrode and the drain electrode, on the second surface side of the barrier layer; and
a polarization layer that is provided between the gate electrode and the drain electrode, from among between the gate electrode and the source electrode and between the gate electrode and the drain electrode on the second surface side of the barrier layer, includes a third nitride semiconductor that contains Al, and has an Al composition that decreases from the barrier layer side toward a third surface side opposite to the barrier layer side.

2. The semiconductor device according to claim 1, wherein the polarization layer extends from an end of the gate electrode on a drain electrode side on a bottom surface that faces the barrier layer, toward the drain electrode side.

3. The semiconductor device according to claim 2, wherein the polarization layer is separated from the drain electrode.

4. The semiconductor device according to claim 2, wherein the polarization layer is in contact with the drain electrode.

5. The semiconductor device according to claim 1, wherein a part of the gate electrode is provided on the third surface of the polarization layer.

6. The semiconductor device according to claim 1, wherein
the second nitride semiconductor of the barrier layer contains Al, and
the third nitride semiconductor of the polarization layer has an Al composition of a fourth surface on the barrier layer side of the polarization layer that is equal to an Al composition of the second surface of the barrier layer.

7. The semiconductor device according to claim 1, wherein regarding the third nitride semiconductor of the polarization layer, an Al composition of a fourth surface on the barrier layer side of the polarization layer is 0.3.

8. The semiconductor device according to claim 1, wherein regarding the third nitride semiconductor of the polarization layer, an Al composition of the third surface is zero.

9. The semiconductor device according to claim 1, wherein a thickness from a fourth surface on the barrier layer side to the third surface opposite to the barrier layer side, of the polarization layer is equal to or less than 40 nm.

10. A method for manufacturing a semiconductor device, the method comprising:
forming a barrier layer that includes a second nitride semiconductor on a first surface side of a channel layer that includes a first nitride semiconductor;
forming a polarization layer that includes a third nitride semiconductor that contains Al, on a second surface side opposite to the channel layer side, of the barrier layer and of which an Al composition decreases from the barrier layer side toward a third surface side opposite to the barrier layer side; and
forming a source electrode and a drain electrode, and a gate electrode provided between the source electrode and the drain electrode, on the second surface side of the barrier layer, wherein
the forming the source electrode, the drain electrode, and the gate electrode includes forming the drain electrode and the gate electrode so that the polarization layer is provided between the gate electrode and the drain electrode, among between the gate electrode and the source electrode and between the gate electrode and the drain electrode.

11. The method according to claim 10, wherein
the forming the polarization layer includes
forming the polarization layer in a first region on the second surface side of the barrier layer, a second region that faces the first region, and a third region between the first region and the second region, and
removing the polarization layer of the first region and the second region, and
the forming the drain electrode and the gate electrode includes
forming the drain electrode in the first region from which the polarization layer is removed and
forming the gate electrode in the second region from which the polarization layer is removed.

12. The method according to claim 10, wherein the forming the drain electrode and the gate electrode includes forming the drain electrode and the gate electrode, so that the polarization layer extends from an end of the gate electrode on the drain electrode side on a bottom surface that faces the barrier layer, toward the drain electrode side.
